(19) United States
(12) Patent Application Publication
(10) Pub. No.: US 2025/0336904 A1
(43) Pub. Date: Oct. 30, 2025

(54) SEMICONDUCTOR MODULE

(71) Applicant: Murata Manufacturing Co., Ltd., Kyoto-fu (JP)

(72) Inventor: Hisatoshi KAWABATA, Nagaokakyo-shi (JP)

(73) Assignee: Murata Manufacturing Co., Ltd., Kyoto-fu (JP)

(21) Appl. No.: 19/258,375

(22) Filed: Jul. 2, 2025

Related U.S. Application Data
(63) Continuation of application No. PCT/JP2023/046639, filed on Dec. 26, 2023.

(30) Foreign Application Priority Data
Jan. 5, 2023 (JP) 2023-000515

(51) Int. Cl. H01L 25/16; H01L 23/00; H01L 23/29; H01L 23/31; H01L 23/66; H05K 1/18

(52) U.S. Cl. CPC H01L 25/165; H01L 23/29; H01L 23/3121; H01L 23/3135; H01L 23/66; H01L 24/32; H05K 1/181; H01L 24/16; H01L 24/73; H01L 2224/16227; H01L 2224/16238; H01L 2224/32227; H01L 2224/73253; H01L 2924/14215; H05K 2201/10189; H05K 2201/10545

(57) ABSTRACT

A substrate has first and second surfaces that face away from each other. A first semiconductor component is mounted on the first surface. A second semiconductor component is mounted on the second surface. A first mold resin on the first surface molds the first semiconductor component. A second mold resin on the second surface molds the second semiconductor component and has a third surface that faces the same direction as the second surface. Conductive columnar terminals pass through the second mold resin from the second surface and reach the third surface. The second semiconductor component includes a circuit formation layer on which an electronic circuit including a transistor is disposed, an insulating support member, and an insulation layer, made of an inorganic insulating material, that is between the circuit formation layer and the support member, and the second semiconductor component is mounted on the second surface.

### CROSS-REFERENCE TO RELATED APPLICATIONS

This application claims benefit of priority to International Patent Application No. PCT/JP2023/046639, filed Dec. 26, 2023, and to Japanese Patent Application No. 2023-000515, filed Jan. 5, 2023, the entire contents of each are incorporated herein by reference.

### BACKGROUND

### Technical Field

The present disclosure relates to a semiconductor module.

### Background Art

There is a known high-frequency module in which a power amplifier and an output matching circuit are mounted on the upper surface, which is one surface of a double-sided mounting board, and a switch circuit and the like are mounted on the lower surface, which is the other surface, as described, for example, in Japanese Unexamined Patent Application Publication No. 2022-18955. Columnar external connection terminals for connecting the power amplifier and the like to the outside are disposed on the lower surface of the double-sided mounting board. The power amplifier and the output matching circuit mounted on the upper surface of the double-sided mounting board are molded by a mold resin, and the switch circuit mounted on the lower surface is molded by another mold resin. The external connection terminals are exposed to the surface of the mold resin on the lower surface.

### SUMMARY

The heat generated by the power amplifier is transferred to an external substrate through mainly the double-sided mounting board and the external connection terminal. In addition, the heat generated by the switch and the like are transferred to an external substrate through mainly the double-sided mounting board and the external connection terminal. Since the heat dissipation path from the power amplifier and the heat dissipation path from the switch and the like are shared with each other, the heat dissipation is worse than that in a structure in which components are mounted on one surface.

Accordingly, the present disclosure provides a semiconductor module in which semiconductor components are mounted on both surfaces of a substrate while a decrease in heat dissipation is suppressed.

According to an aspect of the present disclosure, there is provided a semiconductor module including a substrate having a first surface and a second surface that face away from each other; a first semiconductor component mounted on the first surface; a second semiconductor component mounted on the second surface; a first mold resin that is disposed on the first surface and molds the first semiconductor component; a second mold resin that is disposed on the second surface, molds the second semiconductor component, and has a third surface that faces the same direction as the second surface; and a plurality of conductive columnar terminals that pass through the second mold resin from the second surface and reach the third surface. The second semiconductor component includes a circuit formation layer on which an electronic circuit including a transistor is disposed, an insulating support member, and an insulation layer, made of an inorganic insulating material, that is disposed between the circuit formation layer and the support member, and wherein the second semiconductor component is mounted on the second surface with the circuit formation layer facing the second surface, and the support member is exposed to the third surface of the second mold resin. The semiconductor module further includes a metal film in contact with the support member exposed to the third surface.

The heat generated by the second semiconductor component is transferred to the outside through mainly the metal film. The heat generated by the first semiconductor component is transferred to the outside through mainly the substrate and the columnar terminals. Since the main heat dissipation paths from the first semiconductor component and the second semiconductor component are different from each other, reduction in heat dissipation caused by the sharing of heat dissipation paths can be suppressed.

### BRIEF DESCRIPTION OF THE DRAWINGS

FIGS. 1A and 1B are a cross-sectional view and a bottom view, respectively, of a semiconductor module according to a first example;

FIG. 2 is a partial cross-sectional view of a second semiconductor component, a substrate, a second mold resin, and the like of the semiconductor module according to the first example;

FIGS. 3A, 3B, and 3C are cross-sectional views of the second semiconductor component of the semiconductor module according to the first example during a manufacturing process;

FIG. 4 is a schematic diagram illustrating heat dissipation paths from heat generating portions of the semiconductor module according to the first example;

FIGS. 5A and 5B are a cross-sectional view and a bottom view, respectively, of the semiconductor module according to a modification of the first example;

FIG. 6A is a cross-sectional view of a semiconductor module according to a second example, and FIG. 6B is a schematic diagram illustrating heat dissipation paths from heat generating portions of the semiconductor module according to the second example; and

FIG. 7 is a cross-sectional view of a semiconductor module according to a modification of the second example.

### DETAILED DESCRIPTION

### First Example

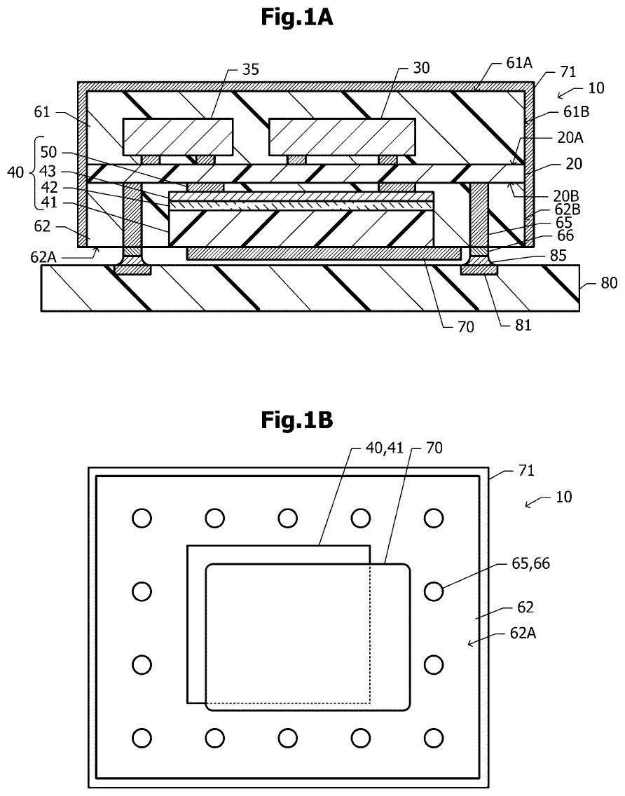

A semiconductor module according to a first example will be described with reference to FIGS. 1A to 4.

FIG. 1A is a cross-sectional view of the semiconductor module 10 according to the first example. The semiconductor module 10 according to the first example includes a substrate 20 capable of mounting electronic components on both surfaces thereof, a first semiconductor component 30, a surface mount device 35, and a second semiconductor component 40. The substrate 20 has a first surface 20A and a second surface 20B that face away from each other. The first semiconductor component 30 and the second semiconductor component 40 are flip-chip-mounted on the first surface 20A and the second surface 20B, respectively, of the substrate 20. The surface mount device 35 is surface-mounted on the first surface 20A of the substrate 20.

A printed circuit board made of a glass epoxy resin, a ceramic substrate, a glass substrate, or the like is used as the substrate 20. The first semiconductor component 30 is, for example, a high-frequency integrated circuit that includes a power amplifier for performing power amplification of high-frequency signals. The power amplifier includes, for example, a heterojunction bipolar transistor or the like. The surface mount device 35 is, for example, a filter or the like. The second semiconductor component 40 is a silicon-based integrated circuit that includes a switch circuit and a low-noise amplifier.

The second semiconductor component 40 includes a circuit formation layer 43 in which an electronic circuit containing transistors is disposed, a support member 41 made of a resin containing a filler, an insulation layer 42, made of an inorganic insulating material, that is disposed between the circuit formation layer 43 and the support member 41, and connection terminals 50. The second semiconductor component 40 is mounted on the second surface 20B of the substrate 20 with the circuit formation layer 43 facing the second surface 20B.

The first mold resin 61 disposed on the first surface 20A of the substrate 20 molds the first semiconductor component 30 and the surface mount device 35. The surface of the first mold resin 61 that faces the same direction as the first surface 20A of the substrate 20 is referred to as a top surface 61A. The surface extending from the edge of the top surface 61A to the substrate 20 is referred to as a side surface 61B.

The second mold resin 62 disposed on the second surface 20B of the substrate 20 molds the second semiconductor component 40. The surface of the second mold resin 62 that faces the same direction as the second surface 20B of the substrate 20 is referred to as a third surface 62A. The surface extending from the third surface 62A to the substrate 20 is referred to as a side surface 62B. The support member 41 of the second semiconductor component 40 is exposed to the third surface 62A of the second mold resin 62.

A plurality of conductive columnar terminals 65 pass through the second mold resin 62 from the second surface 20B of the substrate 20 and reach the third surface 62A. The surface at a front end of each of the plurality of columnar terminals 65 is exposed to the third surface 62A. A pad 66 is disposed on the surface at the front end of each of the plurality of columnar terminals 65. A metal film 70 is in contact with the surface of the support member 41 exposed to the third surface 62A of the second mold resin 62. Here, “contact” refers not only to direct contact but also contact or heat transfer via a thermal conduction film or the like. The pad 66 is formed by, for example, electroless plating. The metal film 70 includes, for example, two layers of a Ni layer and an Au layer. For example, the Ni layer is formed by using plating or sputtering, and the Au layer is formed by using plating.

A plurality of lands 81 are disposed on a mounting surface of a mounting substrate 80 on which the semiconductor module 10 is mounted. The plurality of pads 66 of the semiconductor module 10 are connected to the plurality of lands 81, respectively, with solder 85, and accordingly, the semiconductor module 10 is mounted on the mounting substrate 80. A microscopic gap is formed between the metal film 70 and the mounting substrate 80. It should be noted that the metal film 70 may be in contact with the mounting surface of the mounting substrate 80.

The top surface 61A and the side surface 61B of the first mold resin 61, the side surface of the substrate 20, and the side surface 62B of the second mold resin 62 are covered with a conductive shielding film 71.

FIG. 1B is a bottom view of the semiconductor module 10 according to the first example. One surface of the support member 41 of the second semiconductor component 40 is exposed to the third surface 62A of the second mold resin 62. In plan view from the third surface 62A (often referred to below simply as “in plan view”), the plurality of columnar terminals 65 are disposed so as to surround the second semiconductor component 40. The pad 66 is disposed on the surface at the front end of each of the plurality of columnar terminals 65. In plan view, a portion of the metal film 70 overlaps a portion of the support member 41 of the second semiconductor component 40. The metal film 70 protrudes from the second semiconductor component 40 in plan view. In other words, the metal film 70 has a portion that does not overlap the second semiconductor component 40 in plan view. Since the metal film 70 protrudes from the second semiconductor component 40, the protruding portion is closer to the columnar terminal 65 than is the second semiconductor component 40.

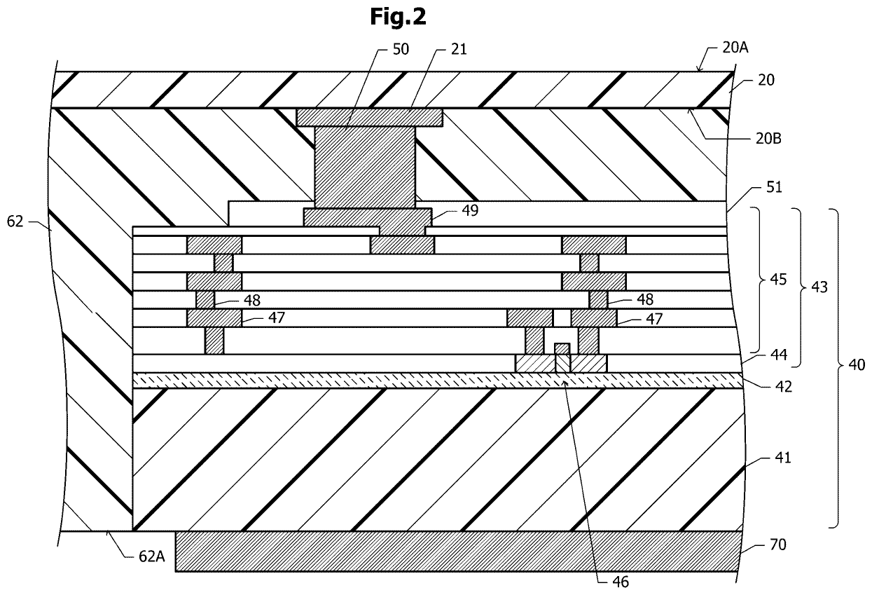

Next, the structure of the second semiconductor component 40 will be described with reference to FIG. 2. FIG. 2 is a partial cross-sectional view of the second semiconductor component 40, the substrate 20, and the second mold resin 62, and the like. The second semiconductor component 40 includes the support member 41, the insulation layer 42, the circuit formation layer 43, and the connection terminals 50. In FIG. 2, one of the plurality of connection terminals 50 is illustrated. The second semiconductor component 40 is flip-chip mounted on the second surface 20B of the substrate 20. In FIG. 2, the direction in which the first surface 20A of the substrate 20 faces is defined as an upward direction, and the direction in which the second surface 20B faces is defined as a downward direction. The circuit formation layer 43 is disposed on the upper surface of the insulation layer 42, and the support member 41 is bonded to the lower surface.

The support member 41 is made of, for example, a polymer, a resin, or the like. It should be noted that the support member 41 contains a filler made of a high-thermal-conductivity material. The material constituting the support member 41 is often referred to as a high-thermal-conductivity resin. It should be noted that the support member 41 may be an insulating ceramic. The ceramic used as the support member 41 preferably has a thermal conductivity approximately the same as that of silicon. The insulation layer 42 is made of an inorganic insulating material, such as, for example, silicon oxide.

The circuit formation layer 43 includes an active layer 44 in contact with the upper surface of the insulation layer 42 and a multilayer wiring structure 45 disposed thereon. The active layer 44 includes an active region made of silicon and an insulating device isolation region that surrounds the active region. A transistor 46 is disposed in the active region of the active layer 44 and thereon. The transistor 46 includes a source region and a drain region that are disposed within the active region of the active layer 44, as well as a gate electrode disposed on the active layer 44 via a gate insulating film. The transistor 46 is, for example, a multi-finger FET, but one source region, one drain region, and one gate electrode are illustrated typically in FIG. 2.

A multilayer wiring structure 45 is disposed on the active layer 44. The multilayer wiring structure 45 includes a plurality of insulation layers. The plurality of insulation layers are made of, for example, a low-permittivity material (low-k material). The uppermost insulation layer is made of, for example, silicon nitride. A plurality of wiring lines 47 and a plurality of vias 48 are disposed in the multilayer wiring structure 45. A plurality of pads 49 are disposed in the uppermost wiring layer of the multilayer wiring structure 45. The wiring lines 47, the vias 48, and the pads 49 are formed by a damascene method, a dual damascene method, or a subtractive method. As an example, the wiring lines 47 and the pads 49 are made of Cu or Al, and the vias 48 are made of Cu or W. It should be noted that a close contact layer made of TiN or the like may be disposed as needed to prevent diffusion or improve close contact.

A protective film 51 made of an organic insulating material is disposed on the circuit formation layer 43 to cover the pads 49. Cavities through which the plurality of pads 49 are exposed are provided in the protective film 51, and the connection terminals 50 are disposed on the pads 49 in the cavities. For example, Cu pillar bumps are used as the connection terminals 50. It should be noted that each of the connection terminals 50 may include an under-bump metal layer and a solder layer.

The connection terminals 50 are connected to the lands 21 of the substrate 20, and accordingly, the second semiconductor component 40 is flip-chip-mounted on the substrate 20. The second semiconductor component 40 is molded by the second mold resin 62.

One surface of the support member 41 is exposed to the third surface 62A of the second mold resin 62. The metal film 70 is in contact with a region of the exposed surface of the support member 41.

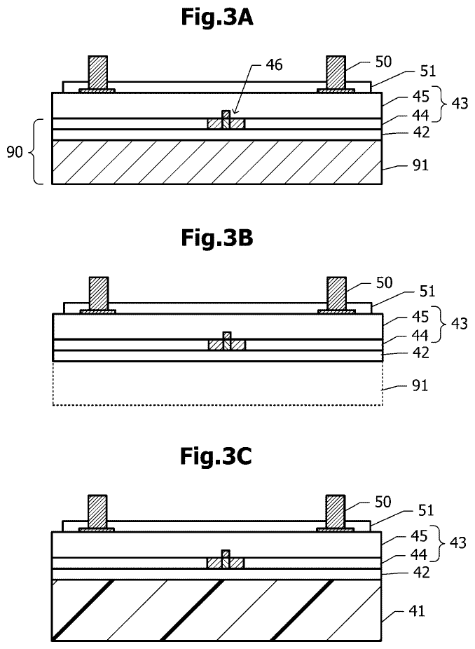

Next, a method of manufacturing the second semiconductor component 40 will be described with reference to FIGS. 3A to 3C. FIGS. 3A, 3B, and 3C are cross-sectional views of the second semiconductor component 40 during a manufacturing process.

An SOI substrate 90 that includes a tentative support substrate 91 made of silicon, the insulation layer 42 made of silicon oxide, and the active layer 44 made of silicon as illustrated in FIG. 3A is prepared. A device isolation region is formed in a portion of the active layer 44, and the transistor 46 is formed in the active region. In addition, the multilayer wiring structure 45 is formed on the active layer 44. The protective film 51 is formed on the multilayer wiring structure 45, and the connection terminals 50 are further formed. These structures can be formed by using general semiconductor wafer processes.

As illustrated in FIG. 3B, the tentative support substrate 91 is removed by etching. In FIG. 3B, the removed tentative support substrate 91 is represented by a dashed line. Before the tentative support substrate 91 is removed by etching, a protective tape (not illustrated) or the like is pasted to the surface opposite to the tentative support substrate 91. The lower surface of the insulation layer 42 is exposed by removal of the tentative support substrate 91.

As illustrated in FIG. 3C, the support member 41 made of a resin is pasted to the lower surface of the insulation layer 42 by using the adhesiveness of the resin. When the support member 41 is made of ceramic, the support member 41 is pasted to the insulation layer 42 using, for example, an adhesive.

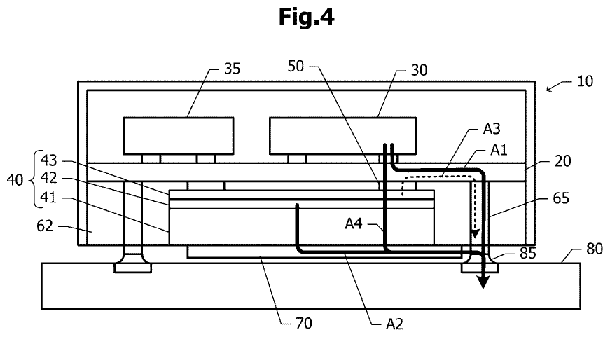

Next, the excellent effects of the first example will be described with reference to FIG. 4. In the first example, as illustrated in FIG. 3B, the tentative support substrate 91 made of silicon is removed, and the insulating support member 41 is pasted instead. When the tentative support substrate 91 is left as is, the high-frequency characteristics of the second semiconductor component 40 decrease due to the conductivity of the tentative support substrate 91. Since the insulating support member 41 is used instead of the tentative support substrate 91 in the first example, the high-frequency characteristics can be suppressed from decreasing.

In addition, since a high-thermal-conductivity resin containing a filler or a ceramic with a thermal conductivity similar to that of silicon is used as the support member 41, heat dissipation similar to that of a structure in which the tentative support substrate 91 is left can be kept.

FIG. 4 is a schematic diagram illustrating heat dissipation paths from heat generating portions of the semiconductor module 10 according to the first example. Of the components of the semiconductor module 10, the first semiconductor component 30 and the second semiconductor component 40 are main heat sources. The heat generated by the first semiconductor component 30 is transferred to the mounting substrate 80 through a heat transfer path including the substrate 20, the columnar terminal 65, and the solder 85, as mainly indicated by arrow A1. The heat generated by the circuit formation layer 43 of the second semiconductor component 40 is transferred to the mounting substrate 80 through a heat transfer path including the insulation layer 42, the support member 41, the metal film 70, the second mold resin 62, and the solder 85, as mainly indicated by arrow A2. Since the metal film 70 is in contact with the support member 41, the thermal resistance of this heat transfer path is reduced, and heat dissipation can be improved. The area of the portion of the second semiconductor component 40 that overlaps the metal film 70 is preferably half or more of the total area in plan view in FIG. 1B to obtain sufficient effects in reducing thermal resistance.

When the thermal resistance of the heat transfer path indicated by arrow A2 is high and does not function sufficiently as a heat transfer path, the heat generated by the circuit formation layer 43 is transferred to the mounting substrate 80 through a heat transfer path including the connection terminal 50, the substrate 20, the columnar terminal 65, and the solder 85 as indicated by dashed arrow A3. The heat transfer path indicated by dashed arrow A3 overlaps the heat transfer path from the first semiconductor component 30 indicated by arrow A1. Accordingly, the heat dissipation from the first semiconductor component 30 and the heat dissipation from the second semiconductor component 40 affect each other, and heat dissipation becomes poor.

In the first example, since the heat transfer path from the second semiconductor component 40, which is indicated by arrow A2, functions effectively, the heat dissipation from the first semiconductor component 30 can be sufficient without being significantly affected by the heat dissipation from the second semiconductor component 40.

In addition, the amount of heat generated by the first semiconductor component 30 that includes a power amplifier for power amplification of high-frequency signals is greater than the amount of heat generated by the second semiconductor component 40. Depending on the temperature difference between the first semiconductor component 30 and the second semiconductor component 40, the second semiconductor component 40 may function as the heat transfer path from the first semiconductor component 30 to the mounting substrate 80, as indicated by arrow A4. Accordingly, the heat dissipation from the first semiconductor component 30 can be improved.

The material of the support member 41 is preferably selected such that the thermal conductivity of the support member 41 is higher than the thermal conductivity of the second mold resin 62 to reduce the thermal resistance of the heat transfer path through the support member 41. For example, when a resin containing a filler is used as the support member 41, the content rate of the filler of the support member 41 is preferably higher than the content rate of the filler of the second mold resin 62. The content rate of the filler of the support member 41 is preferably determined with an emphasis on thermal conductivity, and the content rate of the filler of the second mold resin 62 is preferably determined with an emphasis on mold function. In addition, the filler for the support member 41 may have a higher thermal conductivity than the filler for the second mold resin 62.

The semiconductor module 10 according to the first example is installed in electronic devices that process high-frequency signals, such as, for example, mobile phones. For example, the semiconductor module 10 is used in Bluetooth (registered trademark) modules, wireless LAN modules, antenna switch modules, and the like. An antenna switch module is disposed, for example, directly below the antenna of an electronic device.

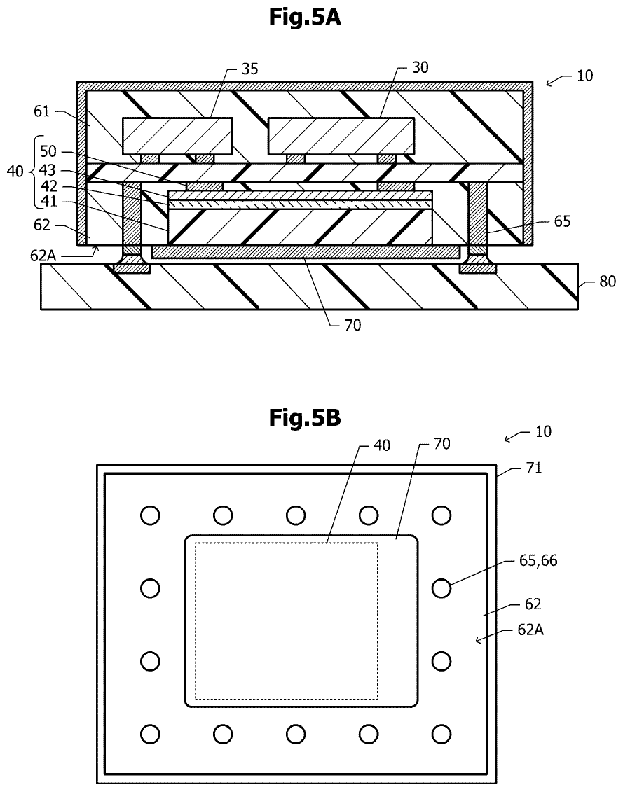

Next, a semiconductor module according to a modification of the first example will be described with reference to FIGS. 5A and 5B. FIGS. 5A and 5B are a cross-sectional view and a bottom view, respectively, of the semiconductor module 10 according to the modification of the first example. In the first example (FIG. 1), a portion of the second semiconductor component 40 overlaps a portion of the metal film 70 in plan view, and the remaining portion of the second semiconductor component 40 does not overlap the metal film 70. On the other hand, in the modification illustrated in FIGS. 5A and 5B, the second semiconductor component 40 is contained in the metal film 70 in plan view. For example, in plan view, the metal film 70 extends in all directions from the second semiconductor component 40. It should be noted that, even when the outer edge of the second semiconductor component 40 perfectly coincides with the outer edge of the metal film 70 in plan view, it can be said that the second semiconductor component 40 is contained in the metal film 70.

Next, the excellent effects of this modification will be described. In this modification, the metal film 70 extends in all directions from the second semiconductor component 40 in plan view. That is, the interface between the support member 41 of the second semiconductor component 40 and the second mold resin 62 is located within the metal film 70 in plan view. The metal film 70 can suppress the reduction in moisture resistance caused by the interface between the support member 41 and the second mold resin 62 to prevent moisture intrusion at this interface.

In addition, as compared with the semiconductor module 10 (FIG. 1B) according to the first example, the metal film 70 comes closer to more of the columnar terminals 65. As a result, the thermal resistance of the heat transfer path from the metal film 70 to the columnar terminal 65 is reduced, and accordingly, heat dissipation can be further improved.

### Second Example

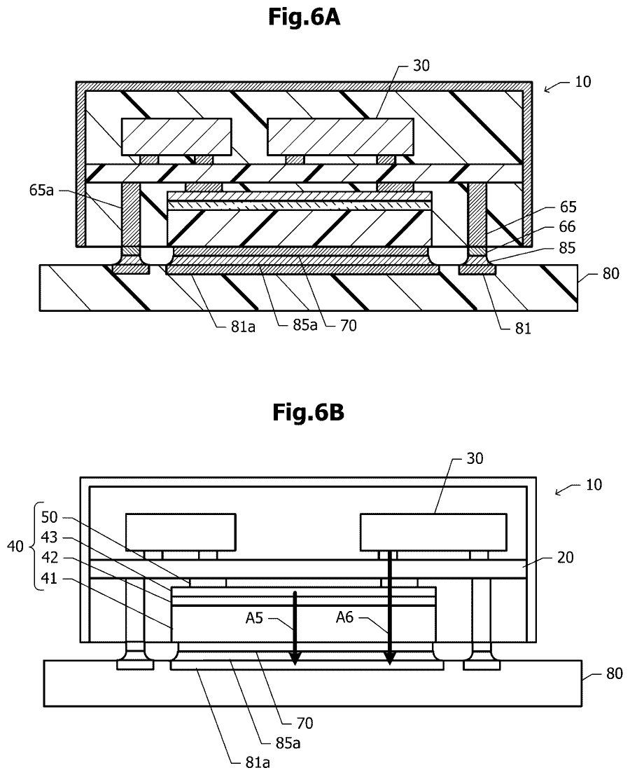

Next, a semiconductor module according to a second example will be described with reference to FIGS. 6A and 6B. The structure in common with the semiconductor module 10 according to the first example described with reference to FIGS. 1A to 4 will not be described.

FIG. 6A is a cross-sectional view of a semiconductor module 10 according to the second example. In the first example (FIG. 1A), a gap is formed between the metal film 70 and the mounting substrate 80. On the other hand, in the second example, a land 81a is disposed in a region of the mounting surface of the mounting substrate 80 that faces the metal film 70, and the metal film 70 is connected to the land 81a with solder 85a.

Next, the excellent effects of the second example will be described with reference to FIG. 6B. FIG. 6B is a schematic diagram illustrating heat dissipation paths from heat generating portions of the semiconductor module 10 according to the second example. In the second example, as indicated by arrow A5, a heat transfer path including the insulation layer 42, the support member 41, the metal film 70, and the solder 85a is formed from the circuit formation layer 43 of the second semiconductor component 40 to the mounting substrate 80. In addition, as indicated by arrow A6, a heat transfer path including the substrate 20, the second semiconductor component 40, the metal film 70, and the solder 85a is formed from the first semiconductor component 30 to the mounting substrate 80. Accordingly, heat dissipation can be further improved as compared with the first example.

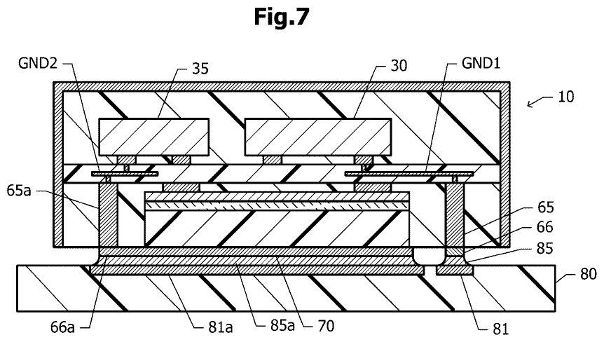

Next, a semiconductor module according to a modification of the second example will be described with reference to FIG. 7. FIG. 7 is a cross-sectional view of a semiconductor module 10 according to the modification of the second example. In the second example (FIG. 6A), the metal film 70 is separated from any of the pads 66 of the semiconductor module 10. On the other hand, in the modification illustrated in FIG. 7, the metal film 70 is connected to at least one of pads 66a.

One land 81a is disposed on the mounting substrate 80 so as to face the metal film 70 and the pad 66a connected to the metal film 70. The metal film 70 and the pad 66a are connected to the land 81a with the solder 85a. A ground conductor GND1 connected to the first semiconductor component 30 and a ground conductor GND2 not connected to the first semiconductor component 30 are disposed in the substrate 20. The ground conductor GND2 is connected to, for example, the surface mount device 35.

The pad 66a connected to the metal film 70 is connected, via a columnar terminal 65a, to the ground conductor GND2 not connected to the first semiconductor component 30. The ground conductor GND1 connected to the first semiconductor component 30 is connected to another columnar terminal 65.

Normally, the ground conductor GND1 connected to the first semiconductor component 30 is used as a heat dissipation path from the first semiconductor component 30. When the metal film 70 is not connected to the ground conductor GND1 connected to the first semiconductor component 30, interference between the heat dissipation path from the first semiconductor component 30 and the heat dissipation paths from other components can be suppressed.

Since the examples described above are illustrative, it will be appreciated that partial substitution or combination of the structures illustrated in different examples can be made. The similar operations and effects resulting from similar structures of a plurality of examples will not be described one by one for each example. In addition, the present disclosure is not limited to the examples described above. For example, it is obvious to those skilled in the art that various modifications, improvements, combinations, and the like can be made.

What is claimed is:

1. A semiconductor module comprising:
a substrate having a first surface and a second surface that face away from each other;
a first semiconductor component mounted on the first surface;
a second semiconductor component mounted on the second surface;
a first mold resin that is on the first surface and molds the first semiconductor component;
a second mold resin that is on the second surface, molds the second semiconductor component, and has a third surface that faces the same direction as the second surface;
a plurality of conductive columnar terminals that pass through the second mold resin from the second surface and reach the third surface,
wherein the second semiconductor component includes a circuit formation layer on which an electronic circuit including a transistor is disposed, an insulating support member, and an insulation layer, including an inorganic insulating material, that is between the circuit formation layer and the insulating support member, and the second semiconductor component is mounted on the second surface with the circuit formation layer facing the second surface, and the insulating support member is exposed to the third surface of the second mold resin; and
a metal film in contact with the insulating support member exposed to the third surface.

2. The semiconductor module according to claim 1, wherein
a thermal conductivity of the insulating support member is higher than a thermal conductivity of the second mold resin.

3. The semiconductor module according to claim 1, wherein
the metal film protrudes from the second semiconductor component in plan view from the second surface.

4. The semiconductor module according to claim 3, wherein
the metal film includes the second semiconductor component in plan view from the second surface.

5. The semiconductor module according to claim 1, wherein
the metal film is connected to at least one of the plurality of conductive columnar terminals.

6. The semiconductor module according to claim 5, wherein
the substrate includes a ground conductor not connected to the first semiconductor component, and
the at least one of the plurality of conductive columnar terminals to which the metal film is connected is connected to the ground conductor.

7. The semiconductor module according to claim 1, further comprising:
a mounting substrate having a plurality of lands to which the plurality of conductive columnar terminals are connected,
wherein the metal film is connected, via solder, to one of the plurality of lands of the mounting substrate.

8. The semiconductor module according to claim 1, wherein
the first semiconductor component includes a power amplifier, and
the second semiconductor component includes at least one of a low-noise amplifier and a switch circuit.

9. The semiconductor module according to claim 2, wherein
the metal film protrudes from the second semiconductor component in plan view from the second surface.

10. The semiconductor module according to claim 2, wherein
the metal film is connected to at least one of the plurality of conductive columnar terminals.

11. The semiconductor module according to claim 3, wherein
the metal film is connected to at least one of the plurality of conductive columnar terminals.

12. The semiconductor module according to claim 4, wherein
the metal film is connected to at least one of the plurality of conductive columnar terminals.

13. The semiconductor module according to claim 2, further comprising:
a mounting substrate having a plurality of lands to which the plurality of conductive columnar terminals are connected,
wherein the metal film is connected, via solder, to one of the plurality of lands of the mounting substrate.

14. The semiconductor module according to claim 3, further comprising:
a mounting substrate having a plurality of lands to which the plurality of conductive columnar terminals are connected,
wherein the metal film is connected, via solder, to one of the plurality of lands of the mounting substrate.

15. The semiconductor module according to claim 4, further comprising:
a mounting substrate having a plurality of lands to which the plurality of conductive columnar terminals are connected,
wherein the metal film is connected, via solder, to one of the plurality of lands of the mounting substrate.

16. The semiconductor module according to claim 5, further comprising:
a mounting substrate having a plurality of lands to which the plurality of conductive columnar terminals are connected,
wherein the metal film is connected, via solder, to one of the plurality of lands of the mounting substrate.

17. The semiconductor module according to claim 2, wherein
the first semiconductor component includes a power amplifier, and
the second semiconductor component includes at least one of a low-noise amplifier and a switch circuit.

18. The semiconductor module according to claim 3, wherein
the first semiconductor component includes a power amplifier, and
the second semiconductor component includes at least one of a low-noise amplifier and a switch circuit.

19. The semiconductor module according to claim 4, wherein
the first semiconductor component includes a power amplifier, and
the second semiconductor component includes at least one of a low-noise amplifier and a switch circuit.

20. The semiconductor module according to claim 5, wherein
the first semiconductor component includes a power amplifier, and
the second semiconductor component includes at least one of a low-noise amplifier and a switch circuit.
